(19) United States
(12) Patent Application Publication
(10) Pub. No.: US 2013/0288409 A1
(43) Pub. Date: Oct. 31, 2013

(54) METHOD FOR MANUFACTURING LIGHT EMITTING DIODE

(71) Applicant: ADVANCED OPTOELECTRONIC TECHNOLOGY INC., (US)

(72) Inventors: PIN-CHUAN CHEN, Hsinchu (TW); HSIN-CHIANG LIN, Hsinchu (TW)

(73) Assignee: ADVANCED OPTOELECTRONIC TECHNOLOGY, INC., Hsinchu Hsien (TW)

(21) Appl. No.: 13/726,193

(22) Filed: Dec. 23, 2012

(30) Foreign Application Priority Data
Apr. 26, 2012 (CN) 201210125770.X

(51) Int. Cl. H01L 33/44

(52) U.S. Cl. CPC H01L 33/44
USPC 438/29

(57) ABSTRACT

An exemplary method for manufacturing an LED includes steps: providing a substrate with a first electrode and a second electrode; providing an isosceles trapezoidal LED chip and making the LED chip electrically connecting the first electrode and the second electrode; providing a mold with a cavity and setting the mold on the substrate to make the LED chip received in the cavity, an outer periphery of the LED chip spaced from confronting edges of the mold defining the cavity to define a channel therebetween, and a width of the channel being uniform; providing phosphor glue and filling the phosphor glue in the channel to make the phosphor glue enclose the LED chip therein; solidifying the phosphor glue to form a phosphor layer covering the LED chip and removing the mold.

### BACKGROUND

1. Technical Field

The present disclosure relates to semiconductor devices and, more particularly, to a method for manufacturing a light emitting diode (LED).

2. Description of Related Art

LEDs have many beneficial characteristics, including low electrical power consumption, low heat generation, long lifetime, small volume, good impact resistance, fast response and excellent stability. These characteristics have enabled the LEDs to be widely used as a light source in electrical appliances and electronic devices.

A conventional method for manufacturing an LED includes following steps: providing a substrate with an LED chip mounted thereon, and dispensing phosphor glue mixed by glue and phosphor on the substrate and enclosing the LED chip therein. Light emitted from the LED chip excites the phosphor in the phosphor glue to emit a light of a different wavelength, which mixes the light from the LED chip obtain a light having a desired color. The phosphor glue is prone to be accumulated on a bottom end at lateral sides of the LED chip due to gravity before solidified. Therefore, a thickness of the phosphor glue at a top end of LED chip is less than that at the lateral sides of the LED chip, which results in an unevenly light output at the top end and the lateral sides of the LED chip during operation of the LED.

What is needed is a method for manufacturing an LED which can overcome the problem of the prior art.

### BRIEF DESCRIPTION OF THE DRAWINGS

FIG. 1 is a flowchart of a method for manufacturing an LED in accordance with an exemplary embodiment of the present disclosure.

FIGS. 2-7 are schematic views showing steps of the method for manufacturing the LED of FIG. 1.

FIG. 8 is an enlarged view of a circled portion VIII of FIG. 7.

### DETAILED DESCRIPTION

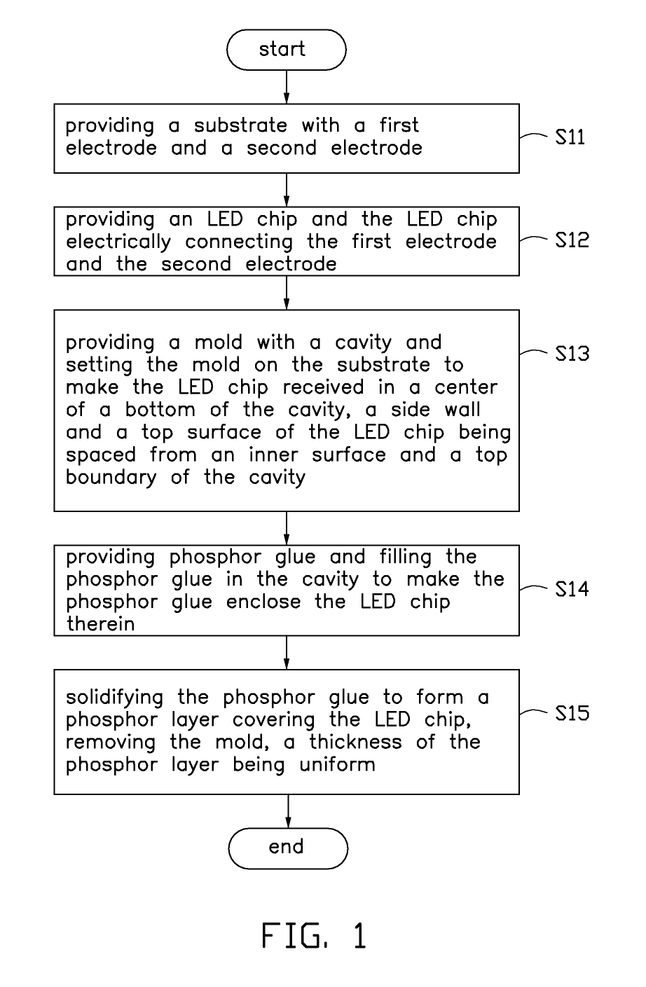

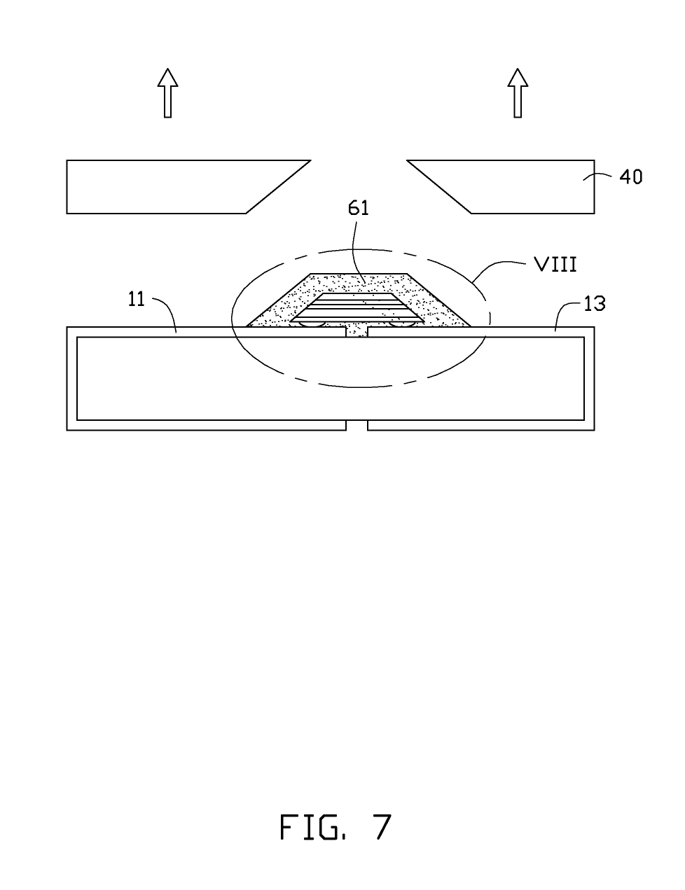

Referring to FIG. 1, a method for manufacturing an LED (shown in FIGS. 7 & 8) in accordance with an exemplary embodiment of the present disclosure includes the following steps.

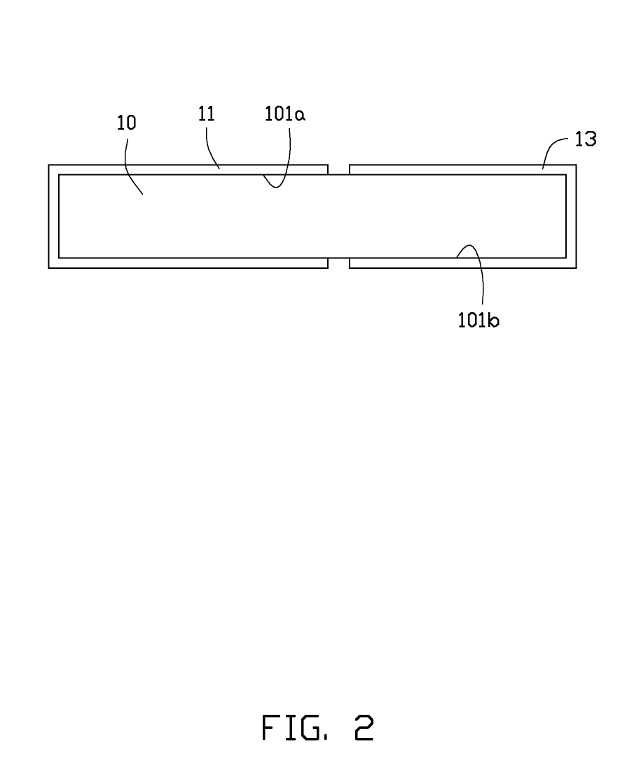

Referring also to FIG. 2, a step S11 is providing a substrate 10 and forming a first electrode 11 and a second electrode 13 on the substrate 10. The substrate 10 includes a top surface 101a and a bottom surface 101b opposite to the top surface 101a. The first electrode 11 is formed on a left side of the top surface 101a and extends to a left side of the bottom surface 101b from a left end of the substrate 10. The second electrode 13 is formed on a right side of the top surface 101a and extends to a right side of the bottom surface 101b from a right end of the substrate 10. The first electrode 11 and the second electrode 13 are spaced from each other. A receiving hole 20 is defined by inner ends of the first electrode 11, the second electrode 13 and the top surface 101a of the substrate 10. The substrate 10 is electrically insulating and made of ceramic or silicon.

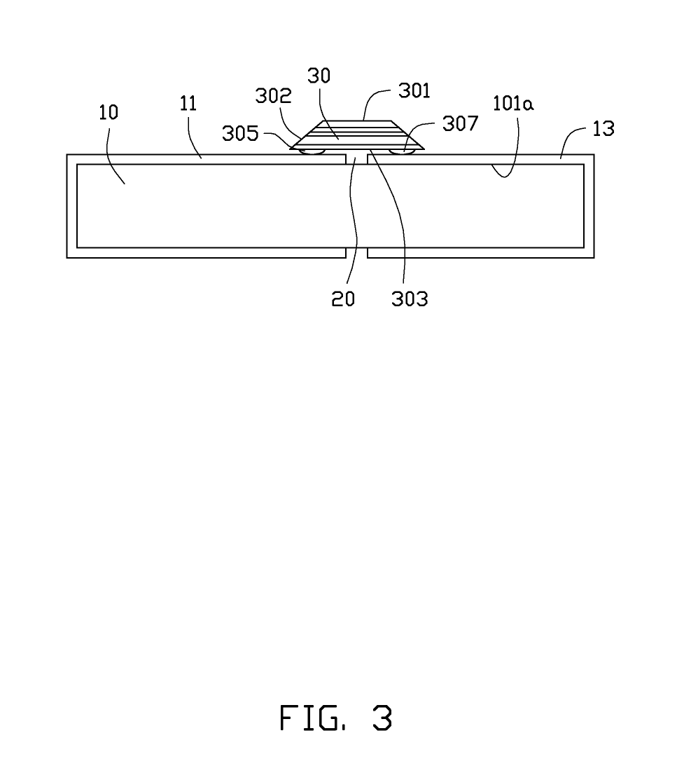

Referring to FIG. 3, a step S12 is providing an LED chip 30 and mounting the LED chip 30 on the substrate 10 to make the LED chip 30 electrically connect the first electrode 11 and the second electrode 13. The LED chip 30 includes a top surface 301, a bottom surface 303 and a side wall 302 connecting the top surface 301 and the bottom surface 303. The top surface 301 is parallel to the bottom surface 303. The LED chip 30 has an isosceles trapezoidal cross section along a height direction thereof. A transverse width of the LED chip 30 increases from the top surface 301 to the bottom surface 303 along the height direction of the LED chip 30. A first electrical connecter 305 and a second electrical connecter 307 are protruded from the bottom surface 303 of the LED chip 30. The first electrical connecter 305 and the second electrical connecter 307 are spaced from each other and respectively electrically contact the first electrode 11 and the second electrode 13. The first and second electrical connectors 305, 307 are solder balls. The LED chip 30 is located at a top side of the receiving hole 20. The bottom surface 303 is spaced from the first electrode 11 and the second electrode 13.

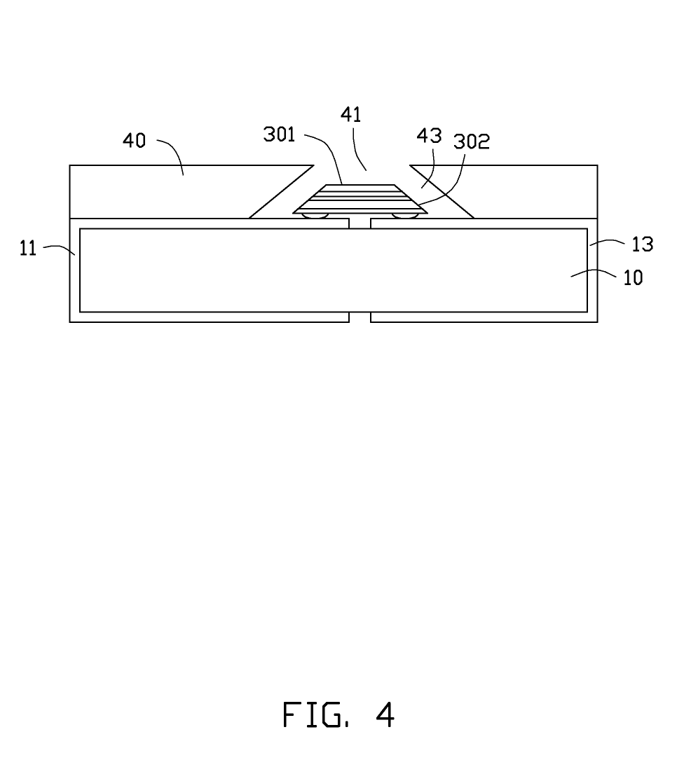

Referring to FIG. 4, a step S13 is providing a mold 40 with a cavity 41 therein, and setting the mold 40 on top surfaces of the first electrode 11 and the second electrode 13 to make the LED chip 30 received in a center of a bottom of the cavity 41. The cavity 41 has an isosceles trapezoidal cross section along a height direction thereof. A transverse width of the cavity 41 of the mold 40 increases from top to bottom. When the LED chip 30 is received in the center of the bottom of the cavity 41, a channel 43 is defined between an outer periphery of the LED chip 30 and confronting edges of the mold 40 defining the cavity 41. A distance between a top of the mold 40 and the top surface 301 (i.e., a depth of the channel 43 above the top surface 301) is equal to a distance between each of the confronting edges of the mold defining the cavity 41 to the correspondingly adjacent side wall 303.

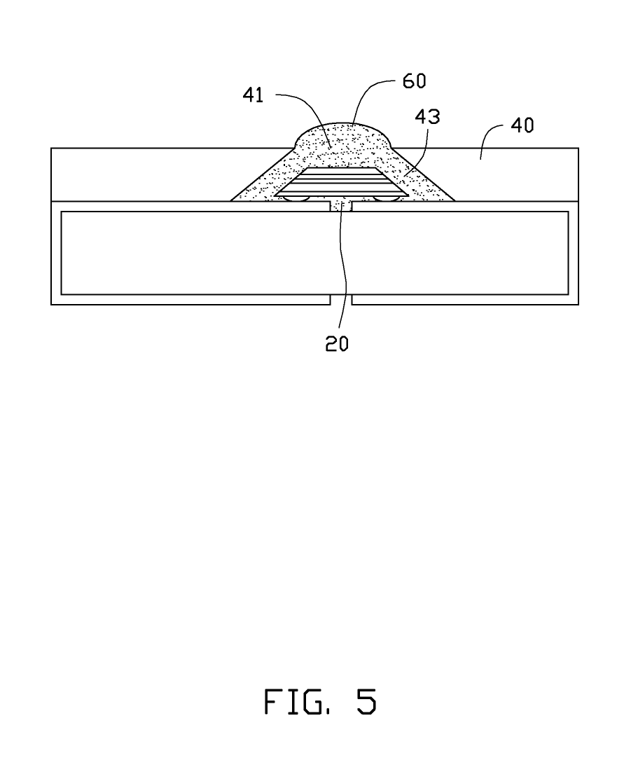

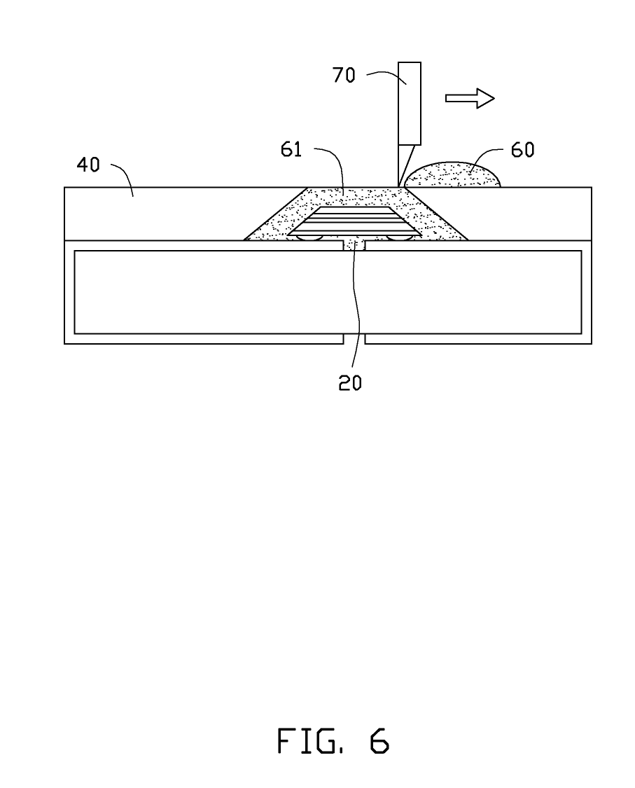

Referring to FIGS. 5-6, a step S14 is providing phosphor glue 60 and filling the phosphor glue 60 in the channel 43. The phosphor glue 60 is formed by transparent glue and phosphor. The phosphor and the transparent glue are evenly mixed. A scraper 70 is provided to slide along a top surface of the mold 40 to scrape a part of the phosphor glue 60 which is higher beyond the top surface of the mold 40. The phosphor glue 60 also fills in the receiving hole 20 to increase a contact area between the phosphor glue 60 LED chip 30 and to increase the binding force between the LED chip 30 and the substrate 10.

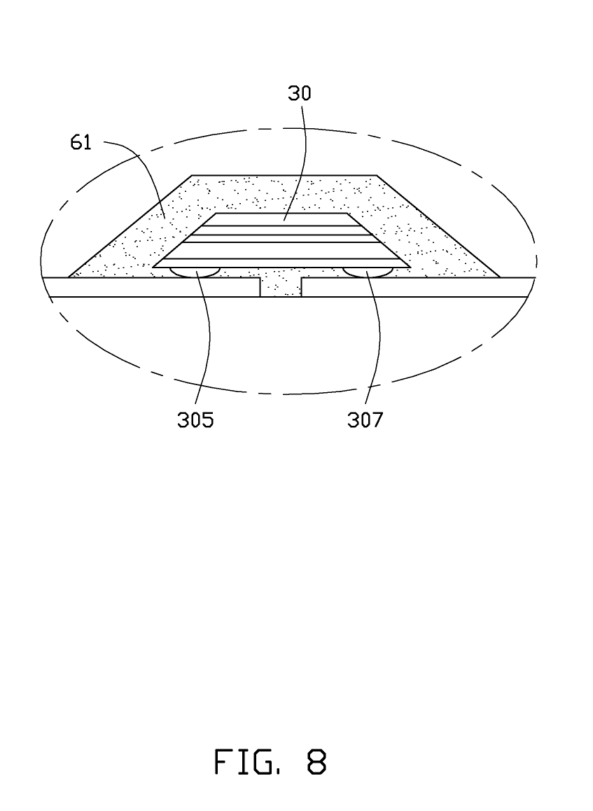

Referring to FIGS. 7-8, a step S15 is solidifying the phosphor glue 60 rapidly to form a phosphor layer 61 covering the LED chip 30 and removing the mold 40 from the phosphor glue 60 and the substrate 10. Thus, the LED is manufactured completely. Because the distance between the top of the mold 40 and the top surface 301 of the LED chip 30 is equal to the distance between the confronting edges of the mold 40 defining the cavity 41 and the side walls 303 of the LED chip 30, a thickness of the phosphor layer 61 on the top surface 301 and the side walls 303 of the LED chip 30 is uniform.

It is understood that, in this embodiment, the thickness of the phosphor layer 61 is uniform, so a light intensity of light from a top side and lateral sides f the LED is uniform.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for manufacturing an LED (light emitting diodes) comprising following steps:
providing a substrate with a first electrode and a second electrode thereon;
providing an isosceles trapezoidal LED chip on the substrate and electrically connecting the LED chip to the first electrode and the second electrode;
providing a mold with a cavity and setting the mold on the substrate to make the LED chip received in a center of a bottom of the cavity, a channel being defined between confronting edges of the mold defining the cavity and a side wall and a top surface of the LED chip;
providing phosphor glue and filling the phosphor glue in the cavity to make the phosphor glue fill in the channel and enclose the LED chip therein;
solidifying the phosphor glue to form a phosphor layer covering the LED chip; and
removing the mold, a thickness of the phosphor layer on the top surface of the LED chip and on the side wall of the LED chip being uniform.

2. The method as claimed in claim 1, wherein a scraper is provided before the phosphor glue is solidified to scrape a part of the phosphor glue higher beyond a top surface of the mold.

3. The method as claimed in claim 1, wherein the phosphor glue is mixed by transparent glue and phosphor.

4. The method as claimed in claim 3, wherein the phosphor powder and the transparent glue are evenly mixed.

5. The method as claimed in claim 1, wherein a first electrical connecter and a second electrical connecter are protruded from a bottom surface of the LED chip and respectively electrically connect the first electrode and the second electrode.

6. The method as claimed in claim 5, wherein the first electrode is formed on a left side of the top surface and extends to a left side of the bottom surface from a left end of the substrate, the second electrode is formed on a right side of the top surface and extends to a right side of the bottom surface from a right end of the substrate.

7. The method as claimed in claim 6, wherein the bottom surface of the LED chip is located at a top of the first and second electrodes, a receiving hole is defined between the first and second electrodes and the bottom surface of the LED chip, and when the phosphor glue is filled in the cavity, the phosphor glue also fills in the receiving hole.

8. A method for manufacturing an LED (light emitting diode) comprising following steps:
providing a first electrode and a second electrode electrically insulating from the first electrode;
providing an isosceles trapezoidal LED chip and electrically connecting the LED chip with the first electrode and the second electrode;
providing a mold with a cavity and setting the mold on the first and second electrodes to make the LED chip received in the cavity, an outer periphery of the LED chip being spaced from confronting edges of the mold defining the cavity to define a channel therebetween, and a width of the channel being uniform;
providing phosphor glue and filling the phosphor glue in the channel to make the phosphor glue enclose the LED chip therein; and
solidifying the phosphor glue to form a phosphor layer covering the LED chip and removing the mold.

9. The method as claimed in claim 8, wherein a scraper is provided before the phosphor glue is solidified to scrape a part of the phosphor glue overflowed from the cavity of the mold.

10. The method as claimed in claim 8, wherein the phosphor glue is mixed by transparent glue and phosphor.

12. The method as claimed in claim 8, wherein a first electrical connecter and a second electrical connecter are protruded from the LED chip and respectively electrically connect the first electrode and the second electrode.
